(19) United States
(12) Patent Application Publication
(10) Pub. No.: US 2026/0250827 A1
(43) Pub. Date: Aug. 27, 2026

(54) DEPOSITION APPARATUS, METHOD OF MANUFACTURING THE DEPOSITION APPARATUS, AND ELECTRONIC DEVICE MANUFACTURED USING THE DEPOSITION APPARATUS

(71) Applicant: Samsung Display Co., LTD., Yongin-si (KR)

(72) Inventors: JEONGKUK KIM, Yongin-si (KR); SUGWOO JUNG, Yongin-si (KR); JIHYUN JUNG, Yongin-si (KR)

(21) Appl. No.: 19/388,097

(22) Filed: Nov. 13, 2025

(30) Foreign Application Priority Data
Feb. 24, 2025 (KR) 10-2025-0023467

(51) Int. Cl. C23C 14/04; H10N 30/082

(52) U.S. Cl. CPC C23C 14/042; H10N 30/082

(57) ABSTRACT

A deposition apparatus includes a stage attached to one side inside a chamber to support a substrate, a mask including a base substrate defining first openings, an insulating film covering the base substrate and defining second openings corresponding to the first openings, and a piezoelectric element which generates current by a piezoelectric effect and includes a first insulating layer, a metal pattern, and a second insulating layer sequentially disposed on the base substrate, and a deposition source disposed below the mask to supply a deposition material to the substrate.

This application claims priority to Korean Patent Application No. 10-2025-0023467, filed on February 24, 2025, and all the benefits accruing therefrom under 35 U.S.C. §119, the content of which in its entirety is herein incorporated by reference.

### BACKGROUND

### 1. Field

Embodiments relate to a deposition apparatus, a method of manufacturing the deposition apparatus, and an electronic device manufactured using the deposition apparatus. More specifically, embodiments relate to a deposition apparatus used in manufacturing micro-organic light emitting diode (OLED), a method of manufacturing the deposition apparatus, and an electronic device manufactured using the deposition apparatus.

### 2. Description of the Related Art

A deposition apparatus is widely used in a manufacturing process of OLED panel, semiconductor device, and other precision instruments, and quality of deposition is generally affected by alignment and contact state between a mask and a substrate.

In a conventional deposition process, when the mask and the substrate are not in close contact with each other, there is a high possibility of reduced pattern precision or non-uniform deposition. Such situations become more prominent, especially in large-area substrates, thereby causing difficulties in productivity and quality control.

### SUMMARY

Although existing technologies provide various structural approaches to align and fix the mask and the substrate, they have limitations in real time monitoring or controlling the contact state. In embodiments of the invention, a piezoelectric element may be disposed on the mask to determine the contact state between the mask and the substrate in real time. The piezoelectric element converts interaction between the substrate and the mask into an electrical signal to determine the contact state, thereby significantly improving the precision of the deposition process and reducing the defect rate.

Embodiments provide a deposition apparatus that minimizes deposition distortion.

Embodiments provide a method of manufacturing the deposition apparatus.

Embodiments provide an electronic device manufactured using the deposition apparatus.

A deposition apparatus according to an embodiment of the present disclosure includes a stage attached to one side inside a chamber, where the stage supports a substrate, a mask including a base substrate defining first openings, an insulating film covering the base substrate and defining second openings corresponding to the first openings, and a piezoelectric element which generates current by a piezoelectric effect, where the piezoelectric element includes a first insulating layer, a metal pattern, and a second insulating layer sequentially disposed on the base substrate, and a deposition source disposed below the mask, where the deposition source supplies a deposition material to the substrate.

In an embodiment, the piezoelectric element may have a semicircular shape convex toward the stage in a cross-sectional view.

In an embodiment, a shortest distance between an upper surface of the base substrate and a central portion of a lower surface of the first insulating layer may be less than or equal to about 7 micrometer (µm).

In an embodiment, the insulating film may include a first insulating film in direct contact with the base substrate, and a second insulating film covering the first insulating film.

In an embodiment, the first insulating film may include silicon oxide, and the second insulating film may include silicon nitride.

In an embodiment, the first insulating layer of the piezoelectric element may include a same material as the first insulating film, and the second insulating layer of the piezoelectric element may include a same material as the second insulating film.

In an embodiment, a thickness of the first insulating layer of the piezoelectric element may be in a range from about 0.1 µm to about 1 µm.

In an embodiment, a thickness of the base substrate may be in a range from about 725 µm to about 775 µm.

In an embodiment, the base substrate may further define a third opening defined corresponding to the piezoelectric element.

In an embodiment, the piezoelectric element may be provided in plural, and a plurality of the piezoelectric elements may be disposed on the base substrate.

In an embodiment, the metal pattern of the piezoelectric element may include at least one selected from aluminum and chromium.

In an embodiment, the deposition apparatus may further include a sensor electrically connected to the piezoelectric element, where the sensor detects a current applied thereto from the piezoelectric element.

A method of manufacturing a deposition apparatus according to an embodiment of the present disclosure includes forming a first insulating film covering a base substrate, forming a metal layer on an upper surface of the first insulating film, forming a second insulating film covering the first insulating film and the metal layer, forming second openings on an upper surface of the second insulating film, etching the metal layer and the first insulating film to form a piezoelectric element including a first insulating layer, a metal pattern, and a second insulating layer, and forming first openings in the base substrate corresponding to the second openings.

In an embodiment, the forming the first openings in the base substrate corresponding to the second openings may be performed simultaneously with forming a third opening in the base substrate corresponding to the piezoelectric element.

In an embodiment, after the forming the third opening, the piezoelectric element may have a convex semicircular shape in a cross-sectional view.

In an embodiment, the forming the second openings on the upper surface of the second insulating film may be performed through a dry etching method.

In an embodiment, the forming the first openings in the base substrate corresponding to the second openings may be performed through a wet etching method.

In an embodiment, in the forming the first insulating film covering the base substrate, the first insulating film may be formed to have a thickness of about 0.1 µm to about 1 µm.

In an embodiment, in the forming the piezoelectric element, a plurality of the piezoelectric elements may be formed on the base substrate.

An electronic device according to an embodiment of the present disclosure includes a display device, and a processor which drives the display device. In such an embodiment, the display device is manufactured by a deposition apparatus including a stage attached to one side inside a chamber, where the stage supports a substrate, a mask including a base substrate defining first openings, an insulating film covering the base substrate and defining second openings corresponding to the first openings, and a piezoelectric element disposed on the base substrate, where the piezoelectric element generates current by a piezoelectric effect, and includes a first insulating layer, a metal pattern, and a second insulating layer, and a deposition source disposed below the mask, where the deposition source supplies a deposition material to the substrate.

In a deposition apparatus according to embodiments of the present disclosure, the deposition apparatus may include a stage attached to one side inside a chamber to support a substrate, a mask including a base substrate defining first openings, an insulating film covering the base substrate and defining second openings corresponding to the first openings, and a piezoelectric element which generates current by a piezoelectric effect and includes a first insulating layer, a metal pattern, and a second insulating layer sequentially disposed on the base substrate, and a deposition source disposed below the mask to supply a deposition material to the substrate.

In such embodiments, as the piezoelectric element and a sensor are disposed in the deposition apparatus, the piezoelectric element may increase precision of alignment of the mask, and may monitor a contact state between the mask and the substrate in real time. As a result, the present disclosure may provide higher reliability and accuracy than conventional technologies in a manufacturing of a display device or the like by utilizing unique characteristics of the piezoelectric element.

### BRIEF DESCRIPTION OF THE DRAWINGS

FIG. 1 is a cross-sectional view illustrating a deposition apparatus according to an embodiment of the present disclosure.

FIG. 2 is a cross-sectional view illustrating an embodiment of a mask and a stage illustrated in FIG. 1.

FIG. 3 is a cross-sectional view illustrating an enlarged view of area A of FIG. 2.

FIG. 4 is a cross-sectional view illustrating an enlarged view of area B of FIG. 2.

FIGS. 5, 6, 7, 8, 9, 10, 11, 12, 13, and 14 are cross-sectional views illustrating a method of manufacturing a mask illustrated in FIG. 2 according to an embodiment of the present disclosure.

FIG. 15 is a block diagram illustrating an electronic device according to an embodiment of the present disclosure.

FIG. 16 is a schematic view illustrating electronic devices according to embodiments of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be understood that when an element is referred to as being “connected” or “coupled” to another element, it may be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for a purpose of describing particular example embodiments only and is not intended to be limiting. As used herein, the singular forms “a,” “an” and “the” are intended to include plural forms as well, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify a presence of stated features, integers, steps, operations, elements, and/or components, but do not preclude the presence or addition of one or more other features, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms (including technical and scientific terms) used herein have a same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings. Same or like reference numerals are used for same or like components in the drawings, and any repetitive detailed descriptions of the same or like components will be omitted or simplified.

In this specification, a plane may be defined by a first direction D1 and a second direction D2 intersecting the first direction D1. For example, the second direction D2 may be perpendicular to the first direction D1. In addition, a third direction D3 may be a normal direction of the plane. That is, the third direction D3 may be perpendicular to the plane formed by the first direction D1 and the second direction D2.

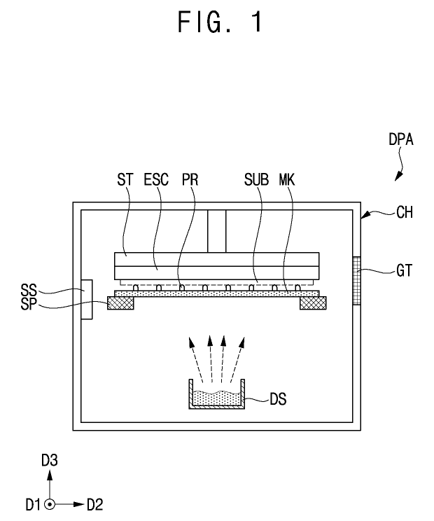

FIG. 1 is a cross-sectional view illustrating a deposition apparatus according to an embodiment of the present disclosure.

Referring to FIG. 1, an embodiment of a deposition apparatus DPA may include a chamber CH, a stage ST, an electrostatic chuck ESC, a deposition source DS, a support member SP, a mask MK, and a sensor SS.

The chamber CB may provide a sealed environment from outside to protect a substrate SUB or the like, and may provide a space in which the substrate SUB is deposited. In an embodiment, for example, the chamber CB may have a vacuum pressure (e.g., about 10 Torr to about 200 Torr) lower than atmospheric pressure (e.g., about 1 atm or about 760 Torr). However, the embodiments of the present disclosure are not limited thereto.

The chamber CB may include at least one gate GT. The chamber CH may be opened and closed by the gate GT. The substrate SUB may enter and exit the chamber CH through the gate GT.

The stage ST may be disposed (or attached) on one side (e.g., an upper side) of the chamber CH. The stage ST may be movable vertically or horizontally. In an embodiment, for example, the stage ST may position the substrate SUB with respect to the mask MK.

An electrostatic inducer such as the electrostatic chuck ESC may be disposed on the stage ST. As a voltage is applied to an electrode of the electrostatic chuck ESC, an electrostatic force may be induced. In an embodiment, for example, the electrostatic chuck ESC may support the substrate SUB by the electrostatic force. That is, the electrostatic chuck ESC may attach the substrate SUB to the stage ST during a deposition process performed in the deposition apparatus DPA. In another embodiment, the electrostatic chuck ESC may be omitted. In such an embodiment, the stage ST and the substrate SUB may be directly attached to (or in direct contact with) each other by a separate fixing member or the like.

The deposition source DS may include a deposition material. The deposition material may be a material capable of sublimation or vaporization, and may include one or more of inorganic or organic materials. The deposition material evaporated from the deposition source DS may pass through the mask MK to be deposited on the substrate SUB.

The support member SP may be disposed on the deposition source DS. The support member SP may support the mask MK. The support member SP may be disposed outside (not to overlap) a movement path of the deposition material supplied from the deposition source DS to the substrate SUB.

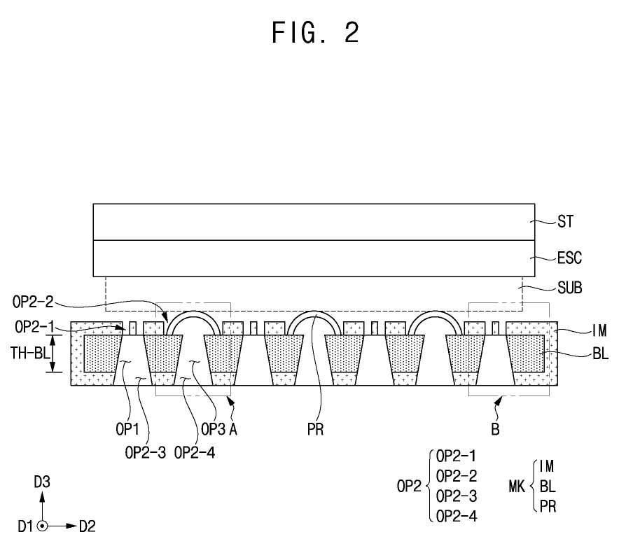

The mask MK may be disposed on the support member SP. The mask MK may define (or be provided with) a plurality of openings such that the deposition material evaporated from the deposition source DS is deposited at selected positions of the substrate SUB. The openings defined in the mask MK will be described below with reference to FIG. 2.

In an embodiment, a piezoelectric element PR may be disposed on the mask MK. The piezoelectric element PR may convert a physical pressure transmitted from outside into an electrical signal. In an embodiment, for example, when the mask MK comes into contact with the substrate SUB disposed on the stage ST, it may be determined whether the mask MK is in contact with the substrate SUB based on a pressure change transmitted to the piezoelectric element PR.

The deposition apparatus DPA may include the sensor SS that detects the electrical signal generated from the piezoelectric element PR. A user of the deposition apparatus DPA may check the sensor SS to determine whether the mask MK is in contact with the substrate SUB. Although FIG. 1 illustrates an embodiment where the sensor SS is disposed inside the deposition apparatus DPA, the embodiments of the present disclosure are not limited thereto. In another embodiment, the sensor SS may be disposed outside the deposition apparatus DPA.

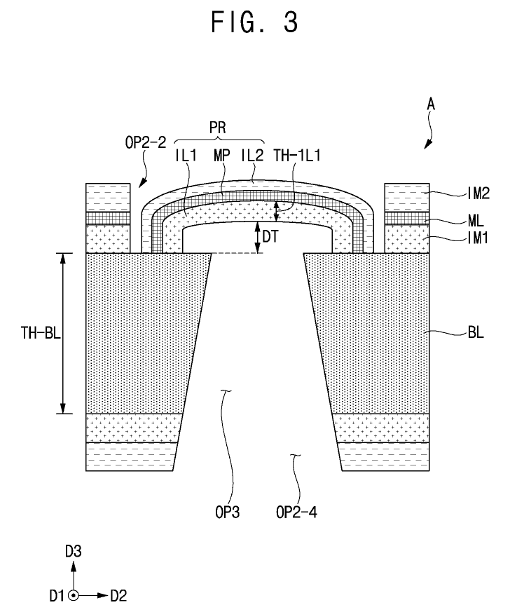

In an embodiment where the piezoelectric element PR and the sensor SS are provided in the deposition apparatus DPA, the piezoelectric element PR may increase precision of alignment of the mask MK, and may monitor a contact state between the mask MK and the substrate SUB in real time. As a result, the present disclosure may provide higher reliability and accuracy than conventional technologies in a manufacturing of a display device or the like by utilizing unique characteristics of the piezoelectric element PR. The piezoelectric element PR will be described below with reference to FIGS. 2 and 3.

FIG. 2 is a cross-sectional view illustrating an embodiment of a mask and a stage illustrated in FIG. 1.

Referring to FIGS. 1 and 2, an embodiment of the mask MK may include a base substrate BL, an insulating film IM, and the piezoelectric element PR.

The base substrate BL may be located inside the mask MK. The base substrate BL may include a metal, a semiconductor material, a ceramic, a polymer, or the like. In an embodiment, for example, the metal included in the base substrate BL may include iron (Fe), platinum (Pt), gold (Au), silver (Ag), indium (In), gallium (Ga), tin (Sn), zirconium (Zr), vanadium (V), hafnium (Hf), cadmium (Cd), germanium (Ge), chromium (Cr), titanium (Ti), zinc (Zn), silicon (Si), or the like. The semiconductor material included in the base substrate BL may include silicon (Si) or the like. These may be used alone or in combination with each other. However, the embodiments of the present disclosure are not limited thereto.

In an embodiment, a thickness TH-BL of the base substrate BL may be in a range from about 700 micrometers (µm) to about 800 µm. In an embodiment, for example, the thickness TH-BL of the base substrate BL may be in a range from about 725 µm to about 775 µm. If the thickness TH-BL of the base substrate BL is less than the above-described range, durability of the base substrate BL may be weakened, and the mask MK may bend during the deposition process. If the thickness TH-BL of the base substrate BL is greater than the above-described range, the deposition material may be deposited on an inner surface of the base substrate BL during the deposition process. That is, by satisfying the above-described thickness TH-BL of the base substrate BL, the deposition material supplied from the deposition source DS may proceed in the third direction D3 with less influence from the inner surface of the base substrate BL.

The insulating film IM may be disposed to cover (or surround) the base substrate BL. The insulating film IM may effectively prevent the base substrate BL and the substrate SUB from being in direct contact with each other. That is, the insulating film IM may effectively prevent the base substrate BL and the substrate SUB from being in direct contact with each other to block a current flow between the base substrate BL and the substrate SUB.

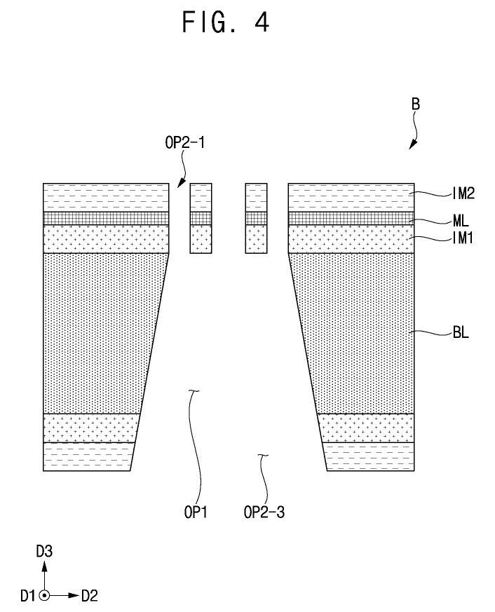

The insulating film IM may include a silicon oxide film, a silicon nitride film, a metal oxide film, or the like. Ina n embodiment, for example, the insulating film IM may include silicon oxide (SiOₓ), silicon nitride (SiNₓ), silicon oxynitride (SiOₓN_{y}), a metal oxide, or the like. These may be used alone or in combination with each other. However, the embodiments of the present disclosure are not limited thereto. The materials included in the insulating film IM will be described below with reference to FIGS. 3 and 4.

In an embodiment, first openings OP1 may be defined in the base substrate BL. Second openings OP2 may be defined in the insulating film IM. The second openings OP2 may include first second openings OP2-1 (hereinafter, will be referred to as “(2-1)th openings”), second second openings OP2-2 (hereinafter, will be referred to as “(2-2)th openings”), third second openings OP2-3 (hereinafter, will be referred to as “(2-3)th openings”), and fourth second openings OP2-4 (hereinafter, will be referred to as “(2-4)th openings”). In an embodiment, for example, the (2-1)th openings OP2-1 and the (2-2)th openings OP2-2 may be located on an upper surface of the base substrate BL in a cross-sectional view. The (2-3)th openings OP2-3 and the (2-4)th openings OP2-4 may be located on a lower surface of the base substrate BL in a cross-sectional view.

In an embodiment, the first openings OP1, the (2-1)th openings OP2-1, and the (2-3)th openings OP2-3 may overlap each other in a plan view or in a thickness direction of the mask MK (e.g., the third direction D3). That is, the first openings OP1, the (2-1)th openings OP2-1, and the (2-3)th openings OP2-3 may be openings defined to allow the deposition material to be deposited at a selected position of the substrate SUB.

In an embodiment, two or more (2-1)th openings OP2-1 may correspond to each of the first openings OP1. That is, the deposition material that has passed through the first openings OP1 may pass through a plurality of (2-1)th openings OP2-1. That is, the (2-1)th openings OP2-1 may form an arbitrary pattern. Accordingly, the deposition material may be deposited on the substrate SUB according to the arbitrary pattern formed by the (2-1)th openings OP2-1.

Third openings OP3 spaced apart from the first openings OP1 may further be defined in the base substrate BL. Each of the third openings OP3 may be defined between the first openings OP1. A cross-sectional shape of each of the third openings OP3 may be substantially the same as a cross-sectional shape of each of the first openings OP1. In an embodiment, for example, the cross-sectional shapes of the first openings OP1 and the third openings OP3 may be trapezoidal.

In an embodiment, each of the third openings OP3 may correspond one-to-one with the piezoelectric element PR disposed on the mask MK. That is, each of the third openings OP3 may overlap the piezoelectric element PR in a plan view. In addition, each of the third openings OP3 may overlap the (2-2)th openings OP2-2 and the (2-4)th openings OP2-4 in a plan view.

The piezoelectric element PR may have a shape convex in the third direction D3 in a cross-sectional view. In an embodiment, for example, the piezoelectric element PR may have a semicircular shape convex toward a direction in which the substrate SUB is located. Accordingly, when the piezoelectric element PR comes into contact with the substrate SUB, the piezoelectric element PR may sensitively detect whether the mask MK is in contact with the substrate SUB. That is, since the piezoelectric element PR does not have a flat shape and has a shape convex in the third direction D3, sensitivity of the piezoelectric element PR may be increased. However, the cross-sectional shape of the piezoelectric element PR is not limited thereto.

In an embodiment, a plurality of piezoelectric elements PR may be disposed on the base substrate BL. In an embodiment, for example, the piezoelectric elements PR may be disposed to correspond one-to-one with the third openings OP3 defined in the base substrate BL.

FIG. 3 is a cross-sectional view illustrating an enlarged view of area A of FIG. 2.

Referring to FIGS. 1, 2, and 3, the piezoelectric element PR may include a first insulating layer IL1, a metal pattern MP, and a second insulating layer IL2. The insulating film IM may include a first insulating film IM1 and a second insulating film IM2. In addition, a metal layer ML may be disposed between the first insulating film IM1 and the second insulating film IM2 in a cross-sectional view.

The first insulating layer IL1 may be disposed on the base substrate BL to overlap the third openings OP3 in a plan view. The first insulating layer IL1 may have a shape convex in the third direction D3. In an embodiment, for example, the first insulating layer IL1 may have a semicircular shape in a cross-sectional view.

In an embodiment, the first insulating layer IL1 may include silicon oxide (SiOₓ). In an embodiment, for example, the first insulating layer IL1 may include SiO₂. In such an embodiment, where the first insulating layer IL1 includes silicon oxide (SiOₓ), the first insulating layer IL1 may have a shape convex in the third direction D3 due to tensile stress applied to the first insulating layer IL1.

In an embodiment, a thickness TH-IL1 of the first insulating layer IL1 in the third direction D3 may be less than or equal to about 1 µm. In an embodiment, for example, the thickness TH-IL1 of the first insulating layer IL1 in the third direction D3 may be in a range from about 0.1 µm to about 1 µm. If the thickness TH-IL1 of the first insulating layer IL1 is greater than the above-described range, the first insulating layer IL1 may expand excessively in the third direction D3 such that damage to the piezoelectric element PR may occur.

In an embodiment, a distance DT between a center portion of a lower surface of the first insulating layer IL1 and an upper surface of the base substrate BL may be less than or equal to about 10 µm. The distance DT refers to a distance measured in the third direction D3 between the center portion of the lower surface of the first insulating layer IL1 and the upper surface of the base substrate BL. In an embodiment, for example, the distance DT may be less than or equal to about 7 µm.

The metal pattern MP may be disposed on the first insulating layer IL1. In an embodiment, the metal pattern MP may be disposed on the first insulating layer IL1 along a profile of the first insulating layer IL1. Accordingly, the metal pattern MP may have a semicircular shape convex in the third direction D3 in a cross-sectional view.

In an embodiment, the metal pattern MP may include aluminum or chromium. These may be used alone or in combination with each other. However, the embodiments of the present disclosure are not limited thereto. The metal pattern MP may further include ceramic, polymer, carbon nanotubes, or the like.

The second insulating layer IL2 may be disposed on the metal pattern MP. In an embodiment, the second insulating layer IL2 may be disposed on the metal pattern MP along a profile of the metal pattern MP. Accordingly, the second insulating layer IL2 may have a semicircular shape convex in the third direction D3 in a cross-sectional view.

In an embodiment, the second insulating layer IL2 may include silicon nitride (SiNₓ). In an embodiment, for example, the second insulating layer IL2 may include SiN₂. Since the second insulating layer IL2 includes silicon nitride (SiNₓ), the second insulating layer IL2 may stably cover the metal pattern MP due to compressive stress applied to the second insulating layer IL2. As a result, the piezoelectric element PR may have a semicircular shape in a cross-sectional view.

The first insulating film IM1 may be disposed on the base substrate BL, and may be in direct contact with the base substrate BL. In an embodiment, the first insulating film IM1 may include a same material as the first insulating layer IL1. In such an embodiment, the first insulating film IM1 may be formed in a same process as the first insulating layer IL1. Accordingly, a thickness of the first insulating film IM1 in the third direction D3 may be substantially the same as the thickness TH-IL1 of the first insulating layer IL1.

The metal layer ML may be disposed on the first insulating film IM1. In an embodiment, the metal layer ML may include a same material as the metal pattern MP. In such an embodiment, the metal layer ML may be formed in the same process as the metal pattern MP. Accordingly, a thickness of the metal layer ML may be substantially the same as a thickness of the metal pattern MP.

The second insulating film IM2 may be disposed on the metal pattern MP. In an embodiment, the second insulating film IM2 may include a same material as the second insulating layer IL2. In such an embodiment, the second insulating film IM2 may be formed in the same process as the second insulating layer IL2. Accordingly, a thickness of the second insulating film IM2 in the third direction D3 may be substantially the same as a thickness of the second insulating layer IL2.

FIG. 4 is a cross-sectional view illustrating an enlarged view of area B of FIG. 2. Specifically, FIG. 4 may be substantially the same as FIG. 3 except for the piezoelectric element PR. Therefore, any repetitive detailed descriptions of the same or like elements described above with reference to FIG. 3 will be omitted or simplified.

Referring to FIGS. 1, 2, 3, and 4, the first openings OP1 may be defined in the base substrate BL of the mask MK. The (2-1)th openings OP2-1 penetrating the first insulating film IM1, the metal layer ML, and the second insulating film IM2 in the third direction D3 may be defined on upper surfaces of the first insulating film IM1 and the second insulating film IM2. The (2-3)th openings OP2-3 penetrating the first insulating film IM1 and the second insulating film IM2 in the third direction D3 may be defined on lower surfaces of the first insulating film IM1 and the second insulating film IM2. The first openings OP1, the (2-1)th openings OP2-1, and the (2-3)th openings OP2-3 may overlap each other in a plan view. Accordingly, the deposition material may sequentially pass through the (2-3)th openings OP2-3, the first openings OP1, and the (2-1)th openings OP2-1 along the third direction D3.

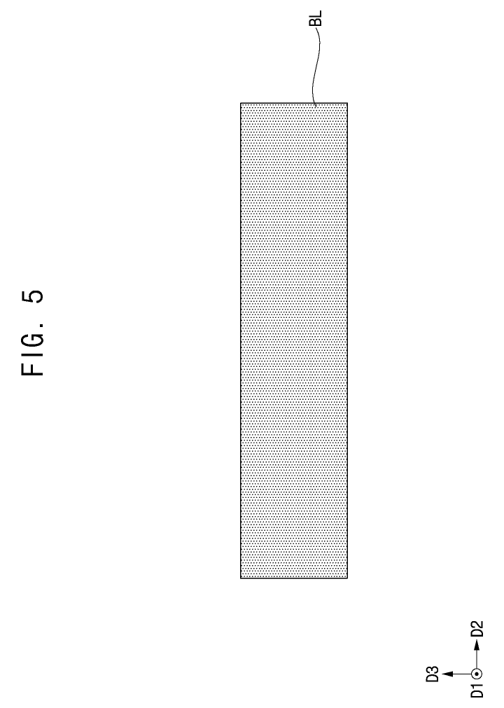

FIGS. 5, 6, 7, 8, 9, 10, 11, 12, 13, and 14 are cross-sectional views illustrating a method of manufacturing a mask illustrated in FIG. 2 according to an embodiment of the present disclosure.

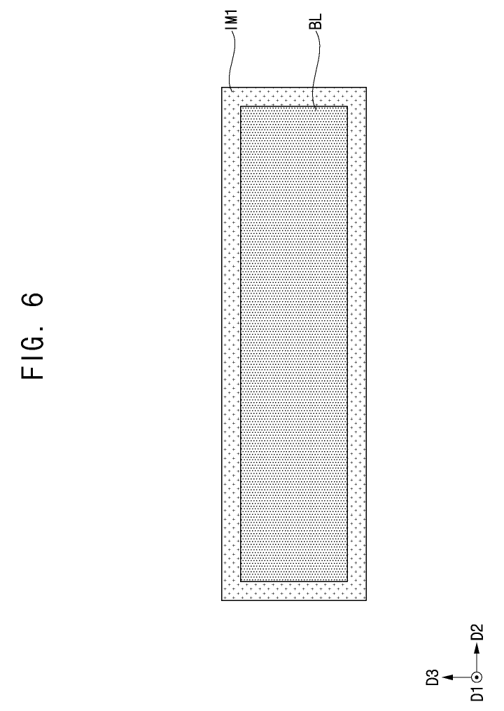

Referring to FIGS. 5 and 6, in an embodiment of a method of manufacturing a mask, the first insulating film IM1 may be formed to cover the base substrate BL. The first insulating film IM1 may be formed to have a uniform thickness on the base substrate BL. In an embodiment, for example, the first insulating film IM1 may include silicon oxide (SiOₓ). However, embodiments of the present disclosure are not limited thereto.

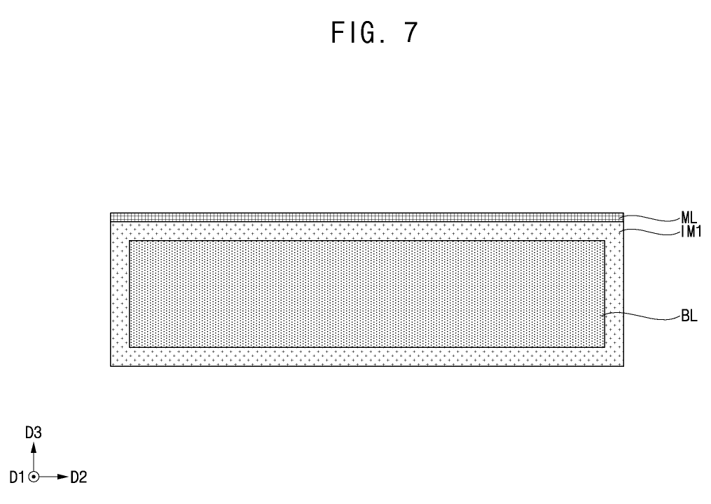

Referring further to FIG. 7, in an embodiment of a method of manufacturing a mask, the metal layer ML may be formed on one surface of the first insulating film IM1. In an embodiment, the metal layer ML may be formed on a surface facing the third direction D3 of the first insulating film IM1. The metal layer ML may be formed to have a uniform thickness on the first insulating film IM1. In an embodiment, for example, the metal layer ML may include aluminum or chromium. However, embodiments of the present disclosure are not limited thereto.

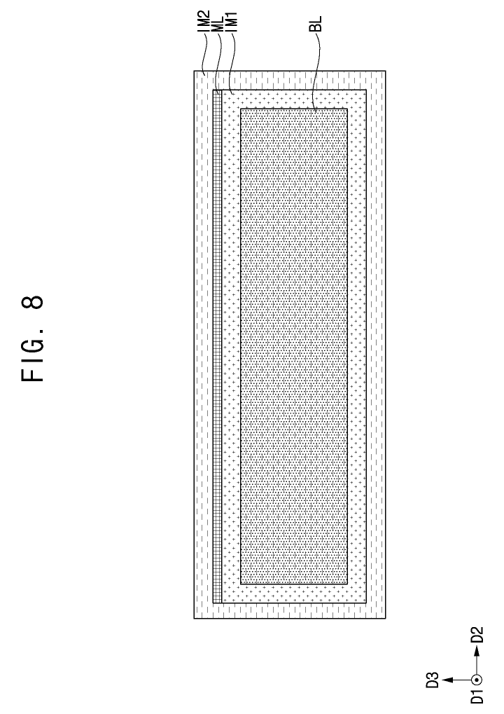

Referring further to FIG. 8, in an embodiment of a method of manufacturing a mask, the second insulating film IM2 may be formed to cover the first insulating film IM1 and the metal layer ML. In such an embodiment, the second insulating film IM2 may cover a side surface and a lower surface of the first insulating film IM1 and an upper surface of the metal layer ML. Accordingly, in a cross-sectional view, the metal layer ML may be disposed between the first insulating film IM1 and the second insulating film IM2. In an embodiment, for example, the second insulating film IM2 may include silicon nitride (SiNₓ). However, embodiments of the present disclosure are not limited thereto.

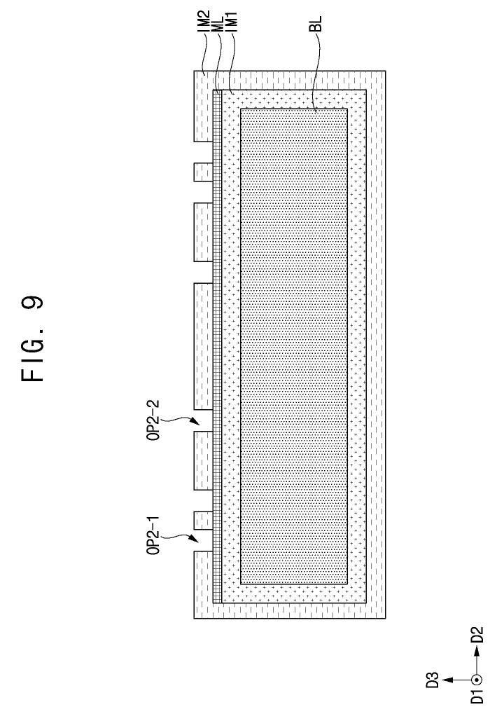

Referring further to FIG. 9, in an embodiment of a method of manufacturing a mask, an etching process may be performed on an upper surface of the second insulating film IM2. As the etching process is performed on the upper surface of the second insulating film IM2, the (2-1)th openings OP2-1 and the (2-2)th openings OP2-2 may be formed in the second insulating film IM2. A pattern of the (2-1)th openings OP2-1 may be formed according to a pattern of the deposition material deposited on the substrate (e.g., the substrate SUB of FIG. 1). That is, the (2-1)th openings OP2-1 may be openings that control deposition positions of the mask (e.g., the mask MK of FIG. 2). Each of the (2-1)th openings OP2-1 and the (2-2)th openings OP2-2 may expose the upper surface of the metal layer ML.

In an embodiment, the etching process for removing the upper surface of the second insulating film IM2 to form the (2-1)th openings OP2-1 and the (2-2)th openings OP2-2 may be a dry etching process. As the etching process to form the (2-1)th openings OP2-1 and the (2-2)th openings OP2-2 is performed by the dry etching process, a pattern of the (2-1)th openings OP2-1 and the (2-2)th openings OP2-2 may be precisely formed. However, embodiments of the present disclosure are not limited thereto.

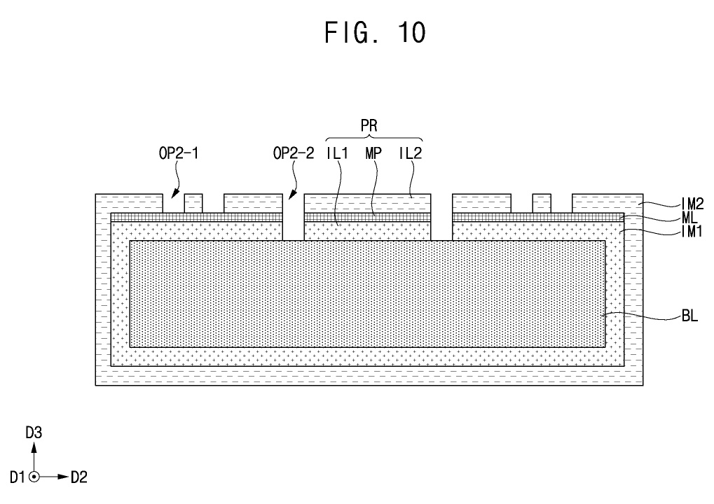

Referring further to FIG. 10, in an embodiment of a method of manufacturing a mask, the (2-2)th openings OP2-2 may be further etched in a direction opposite to the third direction D3. In an embodiment, an etching process may be sequentially performed on the metal layer ML and the first insulating film IM1 exposed by the (2-2)th openings OP2-2 to expose an upper surface of the base substrate BL. As the etching process is performed on the (2-2)th openings OP2-2 and the upper surface of the base substrate BL is exposed, the first insulating film IM1 may be formed as the first insulating layer IL1, the metal layer ML may be formed as the metal pattern MP, and the second insulating film IM2 may be formed as the second insulating layer IL2. That is, the (2-2)th openings OP2-2 may be further etched to form the piezoelectric element PR including the first insulating layer IL1, the metal pattern MP, and the second insulating layer IL2.

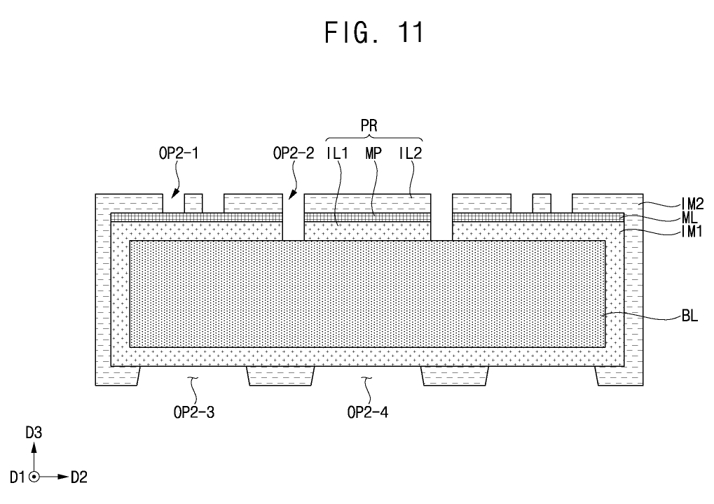

Referring further to FIG. 11, in an embodiment of a method of manufacturing a mask, the (2-3)th openings OP2-3 and the (2-4)th openings OP2-4 may be formed on a lower surface of the second insulating film IM2. The (2-3)th openings OP2-3 and the (2-4)th openings OP2-4 may be formed by etching a portion of the second insulating film IM2, and may expose the lower surface of the first insulating film IM1. In an embodiment, for example, the (2-3)th openings OP2-3 may overlap the (2-1)th openings OP2-1 in a plan view, and the (2-4)th openings OP2-4 may overlap the piezoelectric element PR in a plan view.

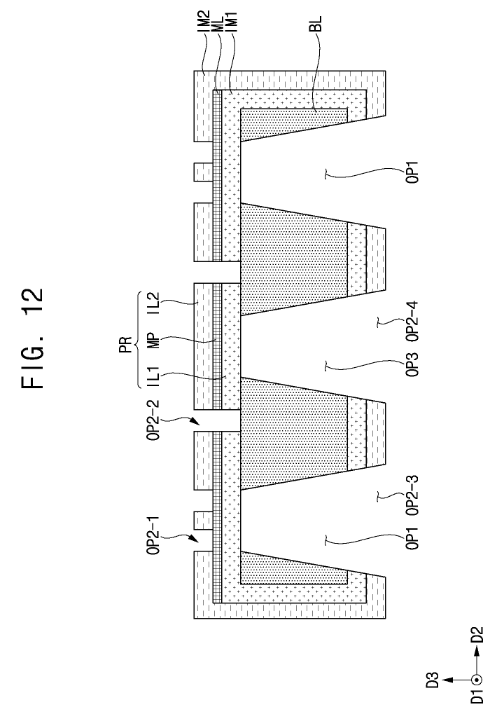

Referring further to FIG. 12, in an embodiment of a method of manufacturing a mask, an etching process may be further performed on the (2-3)th openings OP2-3 and the (2-4)th openings OP2-4. That is, the etching process may be further performed in the third direction D3 on the metal layer ML to form openings in the first insulating film IM1 and the base substrate BL. In an embodiment, for example, the etching process may be further performed along the (2-3)th openings OP2-3 to form the first openings OP1 in the base substrate BL. The etching process may be further performed along the (2-4)th openings OP2-4 to further form the third openings OP3 in the base substrate BL. The first openings OP1 may overlap the (2-1)th openings OP2-1 in a plan view, and the third openings OP3 may overlap the piezoelectric element PR in a plan view.

In an embodiment, the etching process to etch the first insulating film IM1 and the base substrate BL may be a wet etching process. However, embodiments of the present disclosure are not limited thereto.

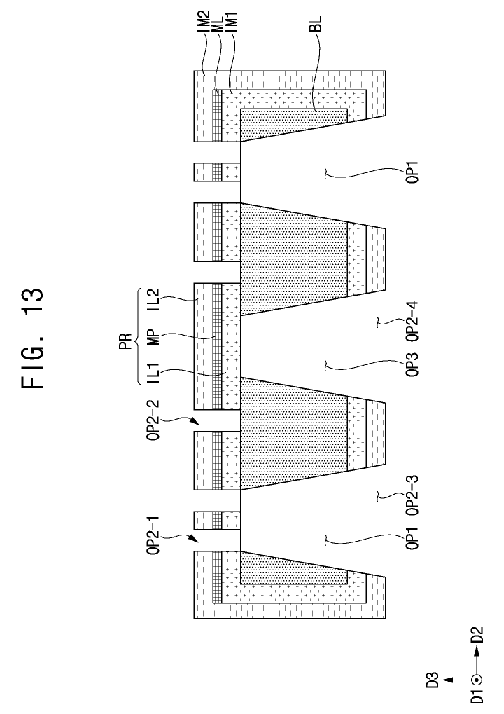

Referring further to FIG. 13, in an embodiment of a method of manufacturing a mask, an etching process may be further performed on the (2-1)th openings OP2-1. In an embodiment, the etching process may be performed on the metal layer ML and the first insulating film IM1 exposed by the (2-1)th openings OP2-1, such that the (2-1)th openings OP2-1 may penetrate the metal layer ML and the first insulating film IM1. Accordingly, the (2-1)th openings OP2-1, the first openings OP1, and the (2-3)th openings OP2-3 may be connected along the third direction D3. As a result, as illustrated in FIG. 13, the deposition material may sequentially pass through the (2-3)th openings OP2-3, the first openings OP1, and the (2-1)th openings OP2-1, and may be deposited on the substrate (e.g., the substrate SUB of FIG. 1).

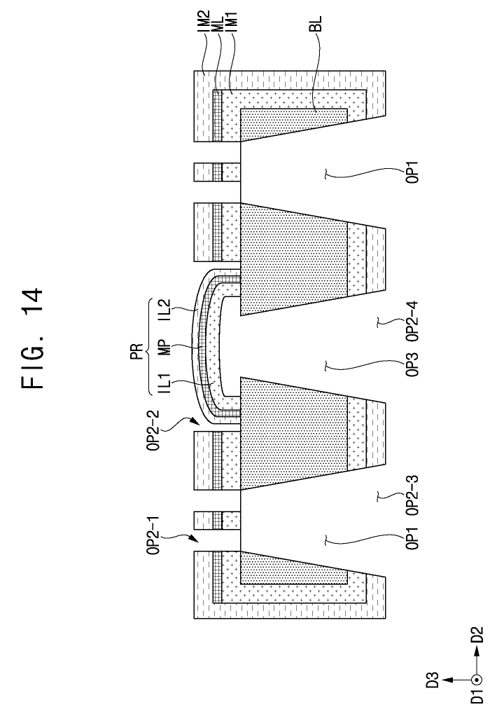

Referring further to FIG. 14, in an embodiment of a method of manufacturing a mask, a lower surface of the first insulating layer IL1 and the base substrate BL may not be in contact with each other by the third openings OP3. The first insulating layer IL1 includes silicon oxide, and due to the tensile strength of the first insulating layer IL1 including the silicon oxide, the first insulating layer IL1 may become convex in the third direction D3. That is, the first insulating layer IL1, which is not in contact with the base substrate BL by the third openings OP3, may be convex in the third direction D3. Accordingly, the piezoelectric element PR may be formed in a semicircular shape convex in the third direction D3 in a cross-sectional view.

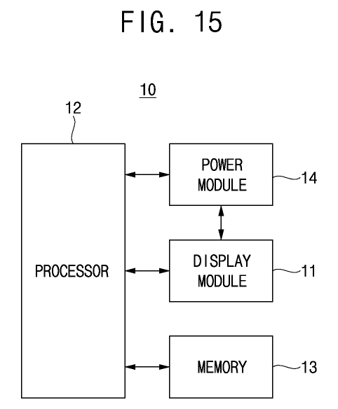

FIG. 15 is a block diagram illustrating an electronic device according to an embodiment of the present disclosure.

Referring to FIGS. 1 and 15, the deposition apparatus DPA according to an embodiment may be applied to a manufacturing process of various electronic devices 10. The electronic device 10 according to an embodiment may include a display device, and may further include a module or device having other additional functions in addition to the display device. The display device may be manufactured using the deposition apparatus DPA.

An embodiment of the electronic device 10 may include a display module 11, a processor 12, a memory 13, and a power module 14.

The processor 12 may include at least one selected from a central processing unit (CPU), an application processor (AP), a graphic processing unit (GPU), a communication processor (CP), and an image signal processor (ISP).

The memory 13 may store data information used for operation of the processor 12 or the display module 11. When the processor 12 executes an application stored in the memory 13, an input image data signal and/or a control signal may be transmitted to the display module 11, and the display module 11 may process the received signal and output image information through a display screen.

The power module 14 may include a power supply module, such as a power adapter or a battery device, and a power conversion module that converts power supplied by the power supply module to generate power used for operation of the electronic device 10.

At least one of components of the electronic device 10 may be included in the display device. In addition, some of individual modules functionally included in one module may be included in the display device, and other portions may be provided separately from the display device. In an embodiment, for example, the display device may include the display module 11, and the processor 12, the memory 13, and the power module 14 may be provided in form of other devices within the electronic device 10 other than the display device.

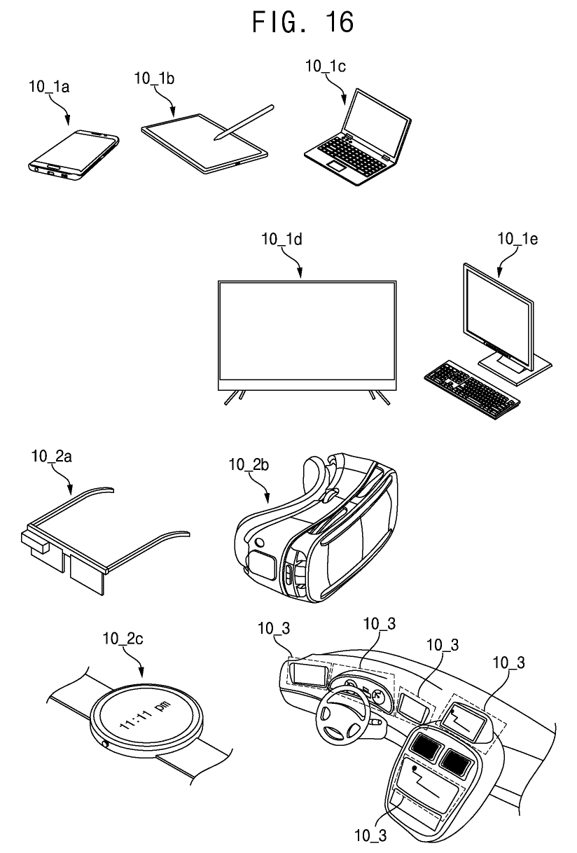

FIG. 16 is a schematic view illustrating electronic devices according to embodiments of the present disclosure.

Referring to FIGS. 15 and 16, various electronic devices 10 manufactured using the deposition apparatus DPA according to an embodiment of the present disclosure may include not only image display electronic devices such as a smartphone 10_1a, a tablet personal computer (PC) 10_1b, a laptop computer 10_1c, a television (TV) 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a center information display (CID) arranged on a cluster, a center fascia, and dashboard of a car, and a room mirror display, or the like.

However, this is merely illustrative, and the electronic device 10 according to embodiments of the present disclosure is not limited thereto. For example, the electronic device 10 may be implemented as a mobile phone, a video phone, a smart pad, a smart watch, a television, a tablet PC, an in-vehicle display, a computer monitor, a laptop, a head-mounted display device, or the like. The electronic device 10 may be an automobile.

The present disclosure can be applied to various display devices and electronic devices, for example, display devices for vehicles, ships and aircraft, portable communication devices, display devices for exhibition or information transmission, medical display devices, and the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition apparatus comprising:
a stage attached to one side inside a chamber, wherein the stage supports a substrate;
a mask including:
a base substrate defining first openings;
an insulating film covering the base substrate and defining second openings corresponding to the first openings; and
a piezoelectric element which generates current by a piezoelectric effect, wherein the piezoelectric element includes a first insulating layer, a metal pattern, and a second insulating layer sequentially disposed on the base substrate; and
a deposition source disposed below the mask, wherein the deposition source supplies a deposition material to the substrate.

2. The deposition apparatus of claim 1, wherein the piezoelectric element has a semicircular shape convex toward the stage in a cross-sectional view.

3. The deposition apparatus of claim 1, wherein a shortest distance between an upper surface of the base substrate and a central portion of a lower surface of the first insulating layer is less than or equal to about 7 µm.

4. The deposition apparatus of claim 1, wherein the insulating film includes:
a first insulating film in direct contact with the base substrate; and
a second insulating film covering the first insulating film.

5. The deposition apparatus of claim 4, wherein:
the first insulating film includes silicon oxide, and
the second insulating film includes silicon nitride.

6. The deposition apparatus of claim 5, wherein:
the first insulating layer of the piezoelectric element includes a same material as the first insulating film, and
the second insulating layer of the piezoelectric element includes a same material as the second insulating film.

7. The deposition apparatus of claim 1, wherein a thickness of the first insulating layer of the piezoelectric element is in a range from about 0.1 µm to about 1 µm.

8. The deposition apparatus of claim 1, wherein a thickness of the base substrate is in a range from about 725 µm to about 775 µm.

9. The deposition apparatus of claim 1, wherein the base substrate further defines a third opening corresponding to the piezoelectric element.

10. The deposition apparatus of claim 1, wherein the piezoelectric element is provided in plural, and a plurality of the piezoelectric elements is disposed on the base substrate.

11. The deposition apparatus of claim 1, wherein the metal pattern of the piezoelectric element includes at least one selected from aluminum and chromium.

12. The deposition apparatus of claim 1, further comprising:
a sensor electrically connected to the piezoelectric element, wherein the sensor detects a current applied thereto from the piezoelectric element.

13. A method of manufacturing a deposition apparatus, the method comprising:
forming a first insulating film covering a base substrate;
forming a metal layer on an upper surface of the first insulating film;
forming a second insulating film covering the first insulating film and the metal layer;
forming second openings on an upper surface of the second insulating film;
etching the metal layer and the first insulating film to form a piezoelectric element including a first insulating layer, a metal pattern, and a second insulating layer; and
forming first openings in the base substrate corresponding to the second openings.

14. The method of claim 13, wherein the forming the first openings in the base substrate corresponding to the second openings is performed simultaneously with forming a third opening in the base substrate corresponding to the piezoelectric element.

15. The method of claim 14, wherein after the forming the third opening, the piezoelectric element has a convex semicircular shape in a cross-sectional view.

16. The method of claim 13, wherein the forming the second openings on the upper surface of the second insulating film is performed through a dry etching method.

17. The method of claim 13, wherein the forming the first openings in the base substrate corresponding to the second openings is performed through a wet etching method.

18. The method of claim 13, wherein in the forming the first insulating film covering the base substrate, the first insulating film is formed to have a thickness of about 0.1 µm to about 1 µm.

19. The method of claim 13, wherein in the forming the piezoelectric element, a plurality of the piezoelectric elements are formed on the base substrate.

20. An electronic device comprising:
a display device; and
a processor which drives the display device,
wherein the display device is manufactured by a deposition apparatus including:
a stage attached to one side inside a chamber, wherein the stage supports a substrate;
a mask including:
a base substrate defining first openings;
an insulating film covering the base substrate and defining second openings corresponding to the first openings; and
a piezoelectric element disposed on the base substrate, wherein the piezoelectric element generates current by a piezoelectric effect, and includes a first insulating layer, a metal pattern, and a second insulating layer; and
a deposition source disposed below the mask, wherein the deposition source supplies a deposition material to the substrate.
